(19) United States
(12) Patent Application Publication
(10) Pub. No.: US 2009/0250708 A1
(43) Pub. Date: Oct. 8, 2009

(54) THIN-FILM PHOTODIODE AND DISPLAY DEVICE

(76) Inventors: Yuki KUDO, Yokohama-shi (JP); Yujiro HARA, Yokohama-shi (JP); Jiro YOSHIDA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/409,921

(22) Filed: Mar. 24, 2009

(30) Foreign Application Priority Data
Mar. 25, 2008 (JP) 2008-078867

(51) Int. Cl. H01L 31/0232; H01L 33/00

(52) U.S. Cl. 257/84; 257/432; 257/E31.127; 257/E33.076

(57) ABSTRACT

A thin-film photodiode has a substrate, a thin-film element formed on the substrate and a micro lens formed above the thin-film element. The thin-film element includes a first semiconductor layer of p-type semiconductor formed on the substrate, a second semiconductor layer formed in contact with the first semiconductor layer on the substrate and formed of i-type semiconductor or p-type semiconductor having lower impurity concentration than the first semiconductor layer and a third semiconductor layer formed of an n-type semiconductor layer formed in contact with the second semiconductor layer on the substrate. The position of an optical axis center of the lens is set between a boundary between the second and third semiconductor layers and a lateral center of the second semiconductor layer.

### CROSS-REFERENCE TO RELATED APPLICATIONS

This application is based upon and claims the benefit of priority from prior Japanese Patent Application No. 2008-078867, filed Mar. 25, 2008, the entire contents of which are incorporated herein by reference.

### BACKGROUND OF THE INVENTION

1. Field of the Invention

This invention relates to a thin-film photodiode that detects illuminance of light and a display device using the photodiode.

2. Description of the Related Art

Recently, a display device using a semiconductor layer of polysilicon or amorphous silicon formed on an insulating substrate by means of the chemical vapor deposition (CVD) method or the like is developed. In the display device, a thin-film photodiode using polysilicon or amorphous silicon as a light receiving element is formed in the peripheral area of a display panel portion having a display function. A so-called dimming function of detecting the illuminance of light from the exterior by means of the thin-film photodiode and adjusting the brightness of the display panel portion is additionally provided.

In order to realize the thin-film photodiode used for this type of application at low cost, it is desirable to form the photodiode by means of the same process as that for forming a thin-film transistor used in the display panel portion. Therefore, as the structure of the thin-film photodiode, the lateral pin structure is provided by arranging semiconductor layers of polysilicon or amorphous silicon of a p⁺ region with high impurity concentration, a p⁻ (or i) region with low impurity concentration and an n⁺ region with high impurity concentration in a direction parallel to the substrate (for example, see Japanese Patent No. 2959682).

The film thickness of the thin-film photodiode with the lateral structure is smaller in comparison with a photodiode with the vertical structure. Therefore, the light absorption amount is small and a current generated when light is made incident, that is, a photocurrent is small. As a result, there is a problem that light with low illuminance cannot be detected.

Further, a region in which carriers such as electrons and holes contributing to the photocurrent is a depletion layer and a region lying near the depletion layer. For example, when an i layer is a p⁻ region having p-type impurity doped therein with low concentration, the depletion layer extends from the boundary between the n⁺ region and the p⁻ region towards the p⁻ region. The length of a portion that contributes to the photocurrent depends on the impurity concentration, the film quality of polysilicon of the p⁻ region and the drive voltage of the photodiode and is set to 1 to 20 μm, for example. On the other hand, the length of the p⁻ region is set to 10 to 30 μm or more and a region that does not contribute to the photocurrent is present depending on the condition (for example, see Jp-A 2006-332287(KOKAI)). Presence of the region that does not contribute to the photocurrent is an important factor that reduces the photocurrent.

### BRIEF SUMMARY OF THE INVENTION

According to one aspect of the present invention, there is provided a thin-film photodiode that includes a substrate, a thin-film element formed on the substrate, the thin-film element including a first semiconductor layer of p-type semiconductor formed on the substrate, a second semiconductor layer formed in contact with the first semiconductor layer on the substrate and formed of one of i-type semiconductor and p-type semiconductor having lower impurity concentration than the first semiconductor layer and a third semiconductor layer formed of an n-type semiconductor layer formed in contact with the second semiconductor layer on the substrate, and a micro lens formed above the thin-film element, a position of an optical axis center of the lens being set between a boundary between the second semiconductor layer and the third semiconductor layer and a lateral center of the second semiconductor layer.

According to another aspect of the present invention, there is provided a thin-film photodiode that includes a substrate, a thin-film element formed on the substrate, the thin-film portion including a first p-type semiconductor layer formed on the substrate and having p-type impurity doped therein with high concentration, a second p-type semiconductor layer formed in contact with the first p-type semiconductor layer on the substrate and having p-type impurity doped therein with low concentration and an n-type semiconductor layer formed in contact with the second p-type semiconductor layer on the substrate and having n-type impurity doped therein, the first p-type semiconductor layer, second p-type semiconductor layer and n-type semiconductor layer being arranged in this order in a direction parallel to the surface of the substrate, and a micro lens insulatively disposed over the thin-film element, an optical axis center of the lens being set between a boundary between the second p-type semiconductor layer and the n-type semiconductor layer and a lateral center of the second p-type semiconductor layer.

According to still another aspect of the present invention, there is provided a display device that includes a substrate, a display panel portion formed by arranging pixels in a matrix form on the substrate, and a thin-film photodiode arranged in a peripheral portion of the display panel portion and formed to detect illuminance of light, the photodiode including a thin-film element that has a first semiconductor layer of p-type semiconductor formed on the substrate, a second semiconductor layer formed in contact with the first semiconductor layer on the substrate and formed of one of i-type semiconductor and p-type semiconductor having lower impurity concentration than the first semiconductor layer and a third semiconductor layer formed of an n-type semiconductor layer formed in contact with the second semiconductor layer on the substrate, and a micro lens formed above the thin-film element, an optical axis center of the lens being set between a boundary between the second semiconductor layer and the third semiconductor layer and a lateral center of the second semiconductor layer.

### BRIEF DESCRIPTION OF THE SEVERAL VIEWS OF THE DRAWING

FIG. 1 is a cross-sectional view showing the schematic structure of a thin-film photodiode according to a first embodiment.

FIG. 2 is a plan view showing the structure of a micro lens used in the first embodiment.

FIG. 3 is a cross-sectional view showing the schematic structure of a thin-film photodiode according to a second embodiment.

FIG. 4 is a cross-sectional view showing the schematic structure of a thin-film photodiode according to a third embodiment.

FIG. 5 is a cross-sectional view showing the schematic structure of a thin-film photodiode according to a fourth embodiment.

FIG. 6 is a plan view showing the structure of a micro lens used in the fourth embodiment.

FIG. 7 is a plan view showing the schematic structure of a display device according to a fifth embodiment.

FIG. 8 is a cross-sectional view showing the schematic structure of a thin-film photodiode used in the fifth embodiment.

FIG. 9 is a cross-sectional view showing the structure of the main portion of a display device according to a sixth embodiment.

### DETAILED DESCRIPTION OF THE INVENTION

Embodiments of the present invention will be explained in detail with reference to the accompanying drawings.

### First Embodiment

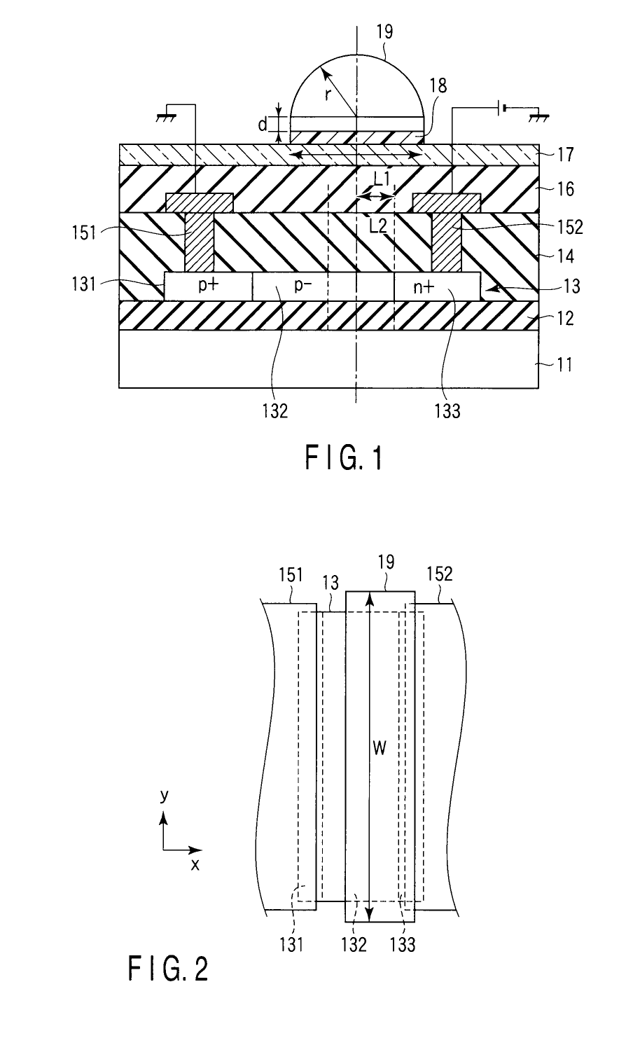

As shown in FIG. 1, an undercoat layer 12 formed of a silicon nitride film, a silicon oxide film or a stacked layer of the above films is formed with a thickness of approximately 150 nm on a glass substrate 11 by means of the plasma CVD method. A polysilicon film 13 is formed as a semiconductor layer with a thickness of 50 nm on part of the undercoat layer 12. The undercoat layer 12 is provided to prevent impurities from being diffused into the polysilicon film 13. The polysilicon film 13 is formed by forming an amorphous silicon layer on the undercoat layer 12 by means of the plasma CVD method and then crystallizing the amorphous silicon layer by application of laser light.

The polysilicon layer 13 is used as a thin-film element that functions as a thin-film photodiode by forming pn junction by impurity doping. That is, in the polysilicon film 13, a p⁺ region (first semiconductor layer) 131 having boron doped therein with high concentration, a p⁻ region (second semiconductor layer) 132 having boron doped therein with low concentration and an n⁺ region (third semiconductor layer) 133 having phosphorus doped therein with high concentration are arranged side by side. The length of the p⁺ region 131 and n⁺ region 133 is set to 15 μm and the length of the p⁻ region 132 is set to 30 μm. Further, the dimension of the thin-film photodiode in the depth direction is 200 μm.

A silicon oxide film 14 is formed with a thickness of approximately 1 μm as an insulating film on the undercoat layer 12 on which the polysilicon film 13 is formed. Contact holes that are respectively communicated with the p⁺ region 131 and n⁺ region 133 are formed in the silicon oxide film 14. An anode electrode 151 is connected to the p⁺ region 131 and a cathode electrode 152 is connected to the n⁺ region 133 via the contact holes. Both of the anode electrode 151 and cathode electrode 152 are formed of laminated films of molybdenum and aluminum and upper layer portions of the respective electrodes are laminated to a thickness of approximately 600 nm on the silicon oxide film 14.

A silicon nitride film 16 is formed with a thickness of approximately 1 μm on the silicon oxide film 14, the anode electrode and the cathode electrode 152. Further, in order to shield an electric field from the exterior, an ITO film 17 is formed on the silicon nitride film 16.

A glass micro lens 19 formed by means of a mold is bonded to the ITO film 17 with an ultraviolet-curable resin film 18 disposed therebetween. The thickness of a bonding layer formed of the ultraviolet-curable resin film 18 is approximately 2 μm. As shown in the cross-sectional view of FIG. 1 and the plan view of FIG. 2, the shape of the micro lens 19 is a cylindrical lens whose cross section is semicircular. As parameters indicating the shape in the drawing, L1=20 μm, r=10 μm, d=3 μm and the dimension W in the depth direction is set to 200 μm.

As shown in FIG. 1, the optical axis center of the micro lens 19 is set to lie between the boundary between the p⁻ region 132 and the n⁺ region 133 and the center of the p⁻ region 132. For example, it is preferable to set L2 to 5 μm, but a sufficiently large effect can be attained even if the bonding position is deviated by approximately ±3 μm when the bonding operation is performed. Further, as shown in FIG. 2, the dimension of the micro lens 19 in the y-direction is set larger than the dimension of the polysilicon film 13 and both end portions thereof in the y-direction are formed with curved surfaces expressed by circles. As a result, light incident on both end portions outside the polysilicon film 13 in the y-direction can be converged into an area that contributes to a large current.

In this case, it is preferable to set the optical axis center of the micro lens 19 in an area in which carriers contributing to the photocurrent in the thin-film element are generated. The area in which carriers contributing to the photocurrent are generated is a depletion layer and an area near the depletion layer. In this embodiment, the depletion layer extends from the boundary between the n⁺ region 133 and the p-region 132 towards the p⁻ region 132. As shown in this embodiment, the optical axis center of the micro lens 19 is positioned in an area in which carriers contributing to the photocurrent in the thin-film element are generated by setting the same to lie between the boundary between the p⁻ region 132 and the n⁺ region 133 and the center of the p⁻ region 132.

In order to operate the thin-film photodiode with the lateral pin structure formed as described above, cathode voltage applied to the cathode electrode 152 is set higher than anode voltage applied to the anode electrode 151. Specifically, as shown in FIG. 1, the anode electrode 151 is grounded and positive voltage is applied to the cathode electrode 152. As a result, reverse bias voltage is applied to the thin-film photodiode.

When light is made incident from above onto the semiconductor layer 13 of the thin-film photodiode applied with the reverse bias voltage, carriers such as electrons and holes are generated and can be derived as a photocurrent. An area that contributes to the photocurrent and in which carriers are generated is mainly a depletion layer and an area near the depletion layer. In this embodiment, this area is defined as a photocurrent generating area. The length of the photocurrent generating area is set to approximately 1 to 20 μm although it depends on the impurity concentration of the p⁻ region 132, the film quality of the polysilicon film and reverse bias voltage. In the thin-film photodiode according to this embodiment, when the reverse bias voltage is set to 5V, it becomes approximately 10 μm from the boundary between the p-region 132 and the n⁺ region 133. Therefore, when L is set to 5 μm, the optical axis center of the micro lens 19 coincides with the center of the photocurrent generating area.

Thus, in the thin-film photodiode according to this embodiment, since light is converged by the lens effect of the micro lens 19, light of a larger amount is applied to the photocurrent generating area in comparison with a case wherein the micro lens 19 is not provided. Further, the amount of light incident on the depletion layer extending from the boundary of the n⁺ region in which a photocurrent is efficiently generated towards the p⁻ region (or i region) and the area lying near the depletion layer can be increased. As a result, a larger photocurrent can be derived in comparison with a case wherein the micro lens 19 is not provided and light with low illuminance can be detected even if the lateral structure is used. The effect depends on the shape of the micro lens 19 and the photocurrent is increased by approximately 1.5 times in comparison with a case wherein the micro lens 19 is not provided.

### Second Embodiment

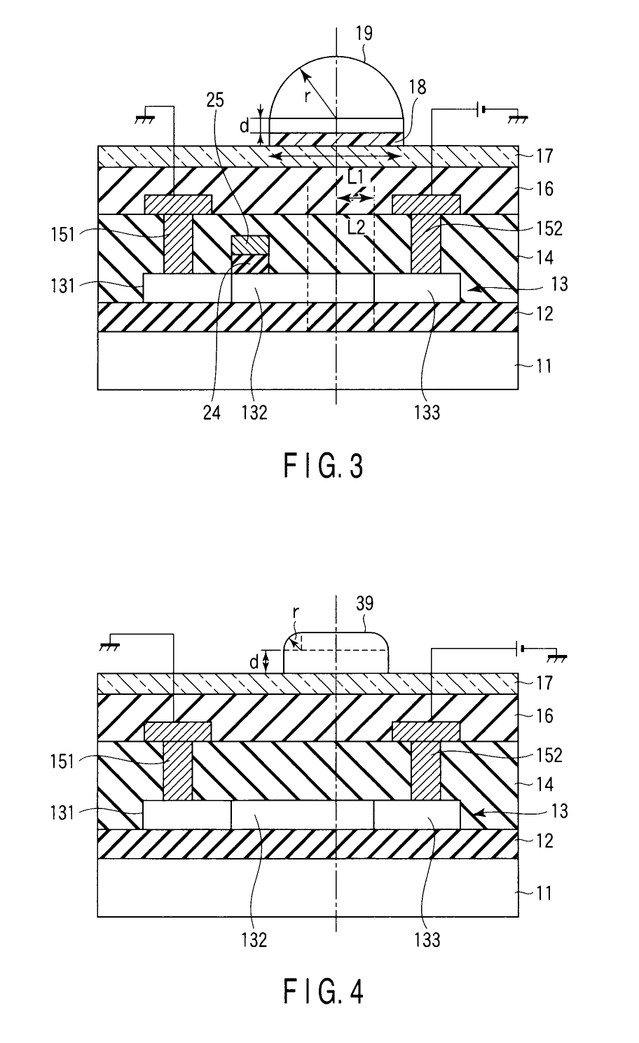

As shown in FIG. 3, the present embodiment is different from the first embodiment explained before in that a gate electrode 25 with a thickness of approximately 300 nm is formed in the silicon oxide film 14. In FIG. 3, portions that are the same as those of FIG. 1 are denoted by the same symbols and the detailed explanation thereof is omitted.

The gate electrode 25 is formed on a p⁻ region 132 in a semiconductor layer 13 with a gate insulating film 24 such as a silicon oxide film disposed therebetween. For example, the thickness of the gate insulating film 24 is 50 to 100 nm and the length of the gate electrode 25 is 5 μm. The material of the gate electrode 25 is a molybdenum-tungsten alloy, for example. The gate electrode 25 is provided to adjust the magnitude of a photocurrent.

The structure other than the structure containing the gate insulating film 24 and gate electrode 25 is substantially the same as that of FIG. 1. Further, the silicon oxide film 14 is formed to cover the gate electrode 25.

In the thin-film photodiode of this embodiment, the amount of light applied to the photocurrent generating area is increased due to the lens effect of the micro lens 19 and a larger photocurrent can be derived in comparison with a case wherein the micro lens 19 is not provided. The material, shape and manufacturing method of the micro lens 19 are the same as those of the first embodiment. In this embodiment, the photocurrent is increased by approximately 1.5 times in comparison with a case wherein the micro lens 19 is not provided.

### Third Embodiment

As shown in FIG. 4, the present embodiment is different from the first embodiment explained before in the structure of the micro lens and the manufacturing method thereof. In FIG. 4, portions that are the same as those of FIG. 1 are denoted by the same symbols and the detailed explanation thereof is omitted.

The process up to the step of forming the ITO film 17 is the same as that of the first embodiment and a micro lens 39 formed of a photosensitive acryl resin film is formed on the ITO film 17 by means of photolithography. The photosensitive acryl resin film has a rectangular cross section when it is formed by means of a lithography technique. However, the end portions of the photosensitive acryl resin film can each be formed into a curved shape with r set to approximately 5 to 10 μm as shown in FIG. 4 by annealing the same at 100 to 200° C. As a result, a semi-cylindrical lens can be formed.

Also, in the thin-film photodiode of this embodiment, like the case shown in the plan view of FIG. 2, the dimension of the micro lens 39 in the y-direction is made larger than the length of the polysilicon film 13. Further, since both end portions of the micro lens 39 are each formed into a curved shape with r set to approximately 5 to 10 μm by annealing, light incident on an area lying outside the polysilicon film 13 can be converged into an area that contributes to a photocurrent.

In the thin-film photodiode of this embodiment, the amount of light applied to the photocurrent generating area is increased due to the lens effect of the micro lens 39 and a larger photocurrent can be derived in comparison with a case wherein the micro lens 39 is not provided. In this embodiment, the photocurrent is increased by approximately 1.2 to 1.5 times in comparison with a case wherein the micro lens 39 is not provided. Further, since photolithography is used as a method for forming the micro lens 39, an advantage wherein a positional shift occurring when the micro lens 39 is formed can be suppressed to a small value can be attained.

### Fourth Embodiment

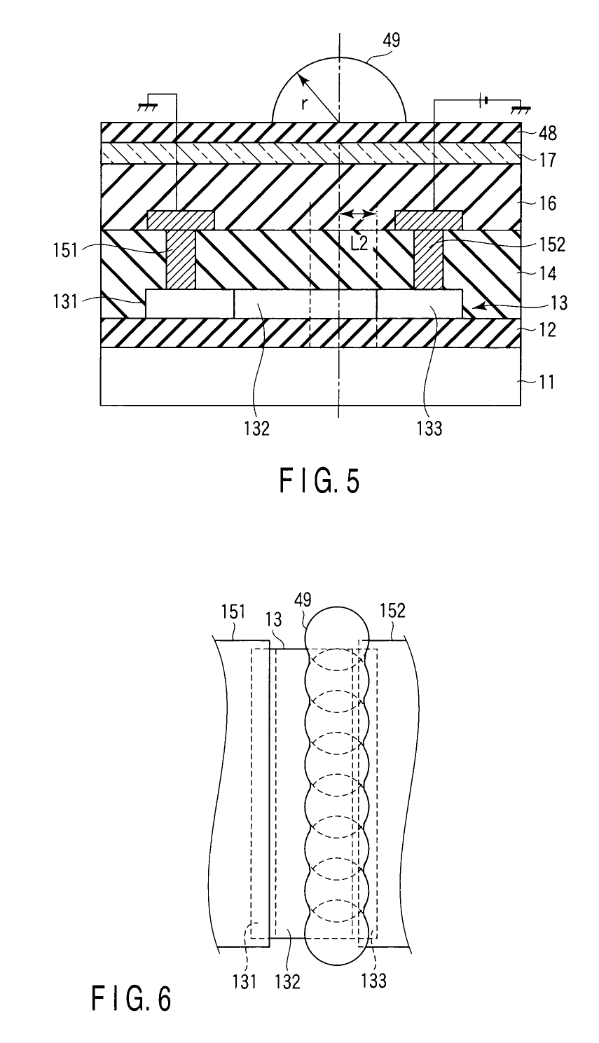

As shown in FIG. 5, the present embodiment is different from the first embodiment explained before in the structure of the micro lens and the manufacturing method thereof. In FIG. 5, portions that are the same as those of FIG. 1 are denoted by the same symbols and the detailed explanation thereof is omitted.

The process up to the step of forming the ITO film 17 is the same as that of the first embodiment and a silicon oxide film 48 is formed with a thickness of approximately 2 μm on the ITO film 17. Then, after ultraviolet-curable resin is coated on the silicon oxide film 48 by means of an ink-jet method, ultraviolet rays are applied to the resin and solidifying the same to form a micro lens 49.

Since a liquid drop of ultraviolet-curable resin is coated by means of the ink-jet method, the lens shape as viewed from above becomes a shape obtained by connecting circles with portions partly overlapped as shown in FIG. 6. Further, the length of the micro lens 49 is made larger than an area in which the photodiode is formed and the amount of light applied to the area that contributes to the photocurrent by the lens effect of the end portions in the y-direction in the drawing can be increased. In this case, since the ink-jet method is used, a process of a phenomenon and a pattern formation step using a mask as in photolithography is not required and an advantage that the process cost can be lowered can be attained. Further, a sufficiently large effect can be attained even when the position of the micro lens 49 in the x-direction is shifted by approximately ±5 μm.

Also, in the thin-film photodiode of this embodiment, the amount of light applied to the photocurrent generating area is increased due to the lens effect of the micro lens 49 and a larger photocurrent can be derived in comparison with a case wherein the micro lens 49 is not provided. In this embodiment, the photocurrent is increased by approximately 1.2 to 1.4 times in comparison with a case wherein the micro lens 49 is not provided.

### Fifth Embodiment

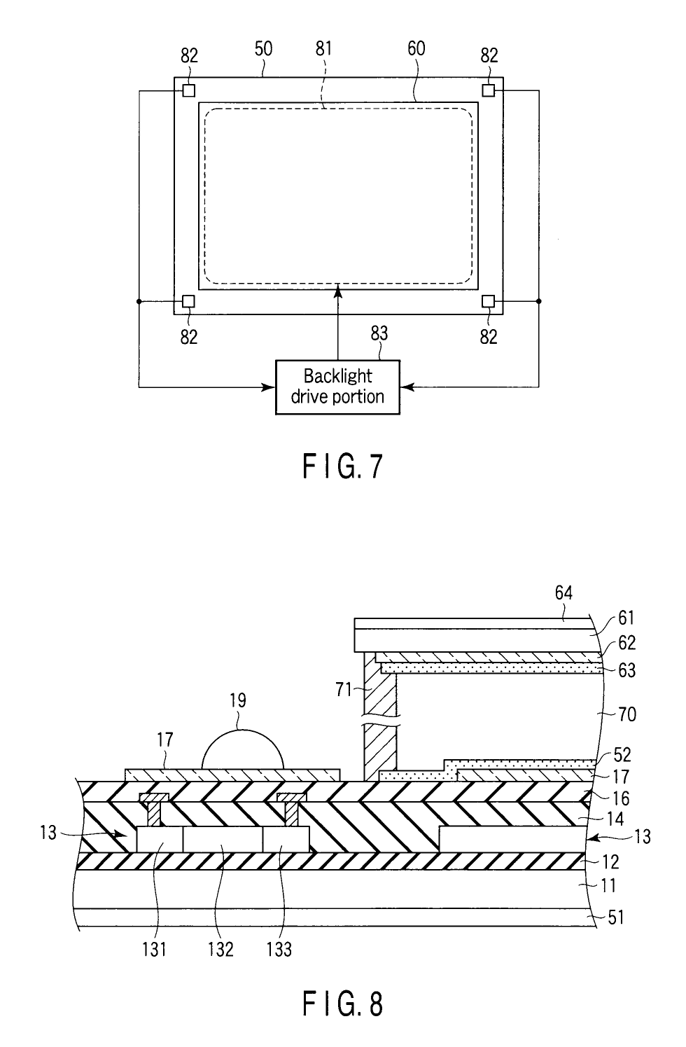

FIG. 7 is a plan view showing the schematic structure of a display device according to a fifth embodiment and FIG. 8 is a cross-sectional view showing the peripheral portion of a display panel portion. In FIG. 8, portions that are the same as those of FIG. 1 are denoted by the same symbols and the detailed explanation thereof is omitted.

As shown in FIG. 7, a display panel portion 60 such as a liquid crystal panel formed by arranging liquid crystal pixels in a matrix form is provided on the front surface side of a substrate 50. A backlight 81 that applies light to the rear surface of the display panel portion 60 is provided on the rear surface side of the display panel portion 60.

Thin-film diodes 82 are arranged around the display panel portion 60 on the front surface side of the substrate 50. Specifically, the thin-film diodes 82 that detect illuminance of exterior light are arranged on the four corners outside the display panel portion 60. Detection signals of the thin-film diodes 82 are supplied to a backlight drive circuit 83 that controls the brightness of the backlight. Thus, the brightness of the display panel portion 60 can be adjusted according to the brightness of the surroundings by controlling the energization current of the backlight 81 of the display panel portion 60 according to the detection outputs of the thin-film diodes 82.

The number of thin-film diodes 82 is not limited to four and it is of course possible to provide one thin-film diode.

As the thin-film diodes 82, any one of the thin-film diodes in the first to fourth embodiments can be used, but in this example, a case using the thin-film diode of the first embodiment is explained.

As shown in FIG. 8, a first glass substrate 11 and a second glass substrate 61 are arranged in opposition to each other to form a liquid crystal display panel portion. The second glass substrate 61 on the upper side is formed smaller than the first glass substrate 11 on the lower side so as to form a photodiode outside the peripheral portion of the liquid crystal display panel portion.

Polysilicon films 13 are formed above the upper surface of the first glass substrate 11 with an undercoat layer 12 disposed therebetween. In the display panel portion, a switching transistor is formed in the polysilicon film 13. In the peripheral portion, a thin-film photodiode is formed in the polysilicon film 13. A silicon oxide film 14 is formed on the polysilicon films and undercoat layer and a silicon nitride film 16 is formed on the silicon oxide film 14. ITO films 17 are formed on the silicon nitride film 16. In the display panel portion, an alignment film 52 is formed on the ITO film 17. Further, a polarization plate 51 is formed on the undersurface of the first glass substrate 11.

An ITO film 62 and alignment film 63 are formed on the undersurface of the second glass substrate 61. A polarization plate 64 is formed on the upper surface of the second glass substrate 61. A seal member 71 is formed between the first glass substrate 11 and the second glass substrate 61. Liquid crystal 70 is introduced into a space between the first glass substrate 11 and the second glass substrate 61. A portion of the seal member 71 that lies on the first glass substrate 11 side is not directly fixed on the first glass substrate 11 and is closely fixed on the silicon nitride film 16.

The same thin-film photodiode as that of the first embodiment is formed outside the display panel portion on the first glass substrate 11. That is, the thin-film photodiode is formed by forming a p⁺ region 131, p⁻ region 132 and n⁺ region 133 by doping impurity into the polysilicon film 13. Then, the same micro lens 19 as that in the first embodiment is formed on the ITO film 17.

With the above structure, the luminance of the display panel portion 60 can be automatically controlled according to the brightness of the surroundings by controlling the energization current of a backlight 81 of the display panel portion 60 based on the detection output of a thin-film photodiode 82. In this case, since an attempt is made to increase a photocurrent by forming the micro lens 19 in the thin-film photodiode, exterior light can be sufficiently detected even when the peripheral portion of the device is dark. Therefore, the brightness of the display panel portion 60 can be effectively adjusted.

### Sixth Embodiment

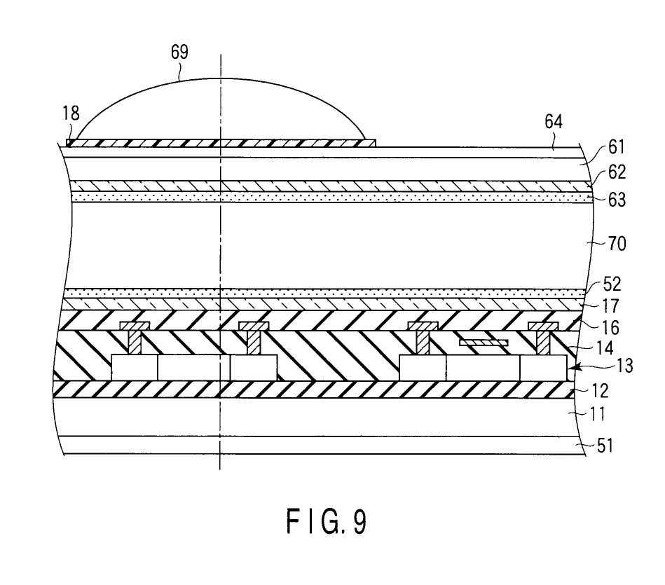

FIG. 9 is a cross-sectional view showing the structure of the main portion of a display device according to a sixth embodiment. In FIG. 9, portions that are the same as those of FIG. 8 are denoted by the same symbols and the detailed explanation thereof is omitted.

A thin-film photodiode used in the present embodiment is formed not outside the peripheral portion of a liquid crystal display panel portion 60 but inside the liquid crystal display panel portion. That is, the thin-film photodiode is formed inside the display portion.

The process up to the step of forming an ITO film 17 is the same as that of the thin-film photodiode of the first embodiment. On the upper portion of the ITO film 17, an alignment film 52 that aligns liquid crystal 70 is formed. An ITO film 62 and alignment film 63 are formed on the undersurface of the second glass substrate 61 used as a counter substrate. The liquid crystal 70 is introduced between the alignment films 52 and 63.

A micro lens 69 formed of glass is bonded to a polarization plate 64 with an ultraviolet-curable resin film 18 disposed therebetween above the thin-film photodiode. As shown in FIG. 9, the micro lens 69 is a circular lens whose cross section is a semicircular shape and the radius r thereof is 400 μm. As shown in FIG. 9, it is preferable to set the optical axis center of the micro lens 69 between the boundary between a p-region 132 and an n⁺ region 133 and the center of the p⁻ region 132. In the present embodiment, for example, L2 is set to 5 μm, but there is no problem even if there is a deviation of approximately several microns.

In the present embodiment, light is made incident via the liquid crystal 70 and a sufficiently large amount of light can be attained by forming the micro lens 69 that is larger than the thin-film photodiode.

In the display device of this embodiment, the amount of light applied to the photocurrent generating area becomes large due to the lens effect of the micro lens 69 and a larger photocurrent can be derived in comparison with a case wherein the micro lens 69 is not provided and the photocurrent is increased by approximately 1.2 to 2 times. Therefore, the same effect as that of the fifth embodiment can be attained. Further, an advantage that it is not required to provide an area in which the thin-film photodiode is disposed outside the display panel portion can be attained.

(Modification)

This invention is not limited to the above embodiments. The semiconductor layer used to configure the thin-film element is not necessarily formed of polysilicon and can be formed of amorphous silicon. Further, as the semiconductor layer, for example, a semiconductor oxide such as IGZO, ZnO or SnO₂ can be used other than silicon.

Further, in the embodiments, the p⁻-type region is formed as the second semiconductor layer that configures the thin-film element, but intrinsic semiconductor (i-type region) in which no impurity is doped can be used instead of the above region. Further, the shape, size, material and the like of the micro lens can be adequately changed according to the specification.

The display panel portion is not necessarily limited to the liquid crystal display panel and it is only necessary to form a display panel portion having pixels arranged in a matrix form. Further, the number of thin-film photodiodes formed in the display panel portion can be adequately changed according to the specification.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A thin-film photodiode comprising:
a substrate,
a thin-film element formed on the substrate, the thin-film element including a first semiconductor layer of p-type semiconductor formed on the substrate, a second semiconductor layer formed in contact with the first semiconductor layer on the substrate and formed of one of i-type semiconductor and p-type semiconductor having lower impurity concentration than the first semiconductor layer, and a third semiconductor layer formed of an n-type semiconductor layer in contact with the second semiconductor layer on the substrate, and
a micro lens formed above the thin-film element, a position of an optical axis center of the lens being set between a boundary between the second semiconductor and the third semiconductor layer and a lateral center of the second semiconductor layer.

2. The photodiode according to claim 1, which further comprises a first insulating film formed on the thin-film element and having contact holes formed to make contact with the first and third semiconductor layers, electrodes formed on portions of the first insulating film to make contact with the first and third semiconductor layers through the contact holes, and a second insulating film formed on the electrodes and the first insulating film, and wherein the micro lens is formed above the second insulating film.

3. The photodiode according to claim 1, further comprising a gate insulating film formed on the thin-film element and a gate electrode formed on the gate insulating film.

4. The photodiode according to claim 2, wherein the micro lens is formed of glass formed by means of a mold and bonded to the second insulating film by using ultraviolet-curable resin.

5. The photodiode according to claim 1, wherein the micro lens is formed of ultraviolet-curable resin.

6. The photodiode according to claim 1, wherein the micro lens is formed of photosensitive acryl resin.

7. The photodiode according to claim 4, wherein the micro lens is a cylindrical lens.

8. The photodiode according to claim 2, wherein the substrate is a substrate on which a display panel portion formed by arranging pixels in a matrix form is formed.

9. A thin-film photodiode comprising:
a substrate,
a thin-film element formed on the substrate, the thin-film portion including a first p-type semiconductor layer formed on the substrate and having p-type impurity doped therein with high concentration, a second p-type semiconductor layer formed in contact with the first p-type semiconductor layer on the substrate and having p-type impurity doped therein with low concentration and an n-type semiconductor layer formed in contact with the second p-type semiconductor layer on the substrate and having n-type impurity doped therein, the first p-type semiconductor layer, second p-type semiconductor layer and n-type semiconductor layer being arranged in this order in a direction parallel to the surface of the substrate, and
a micro lens insulatively disposed over the thin-film element, an optical axis center of the lens being set between a boundary between the second p-type semiconductor layer and the n-type semiconductor layer and a lateral center of the second p-type semiconductor layer.

10. The photodiode according to claim 9, which further comprises a first insulating film formed on the thin-film element and having contact holes formed to make contacts with the first and third semiconductor layers, electrodes formed on portions of the first insulating film to make contact with the first and third semiconductor layers through the contact holes, and a second insulating film formed on the electrodes and first insulating film, and wherein the micro lens is formed above the second insulating film.

11. The photodiode according to claim 9, further comprising a gate insulating film formed on the thin-film element and a gate electrode formed on the gate insulating film.

12. The photodiode according to claim 10, wherein the micro lens is formed of glass formed by means of a mold and bonded to the second insulating film by using ultraviolet-curable resin.

13. The photodiode according to claim 9, wherein the micro lens is formed of ultraviolet-curable resin.

14. The photodiode according to claim 9, wherein the micro lens is formed of photosensitive acryl resin.

15. The photodiode according to claim 12, wherein the micro lens is a cylindrical lens.

16. The photodiode according to claim 9, wherein the substrate is a substrate on which a display panel portion formed by arranging pixels in a matrix form is formed.

17. A display device comprising:
a substrate,
a display panel portion formed by arranging pixels in a matrix form on the substrate, and
a thin-film photodiode arranged in a peripheral portion of the display panel portion and formed to detect illuminance of light, the photodiode including a thin-film element that has a first semiconductor layer of p-type semiconductor formed on the substrate, a second semiconductor layer formed in contact with the first semiconductor layer on the substrate and formed of one of i-type semiconductor and p-type semiconductor having lower impurity concentration than the first semiconductor layer and a third semiconductor layer formed of an n-type semiconductor layer formed in contact with the second semiconductor layer on the substrate, and a micro lens formed above the thin-film element, an optical axis center of the lens being set between a boundary between the second semiconductor layer and the third semiconductor layer and a lateral center of the second semiconductor layer.

18. The device according to claim 17, wherein the thin-film photodiode is arranged outside the display panel portion.

19. The device according to claim 17, wherein the thin-film photodiode is arranged inside the display panel portion.

20. The device according to claim 17, in which the display panel portion has a backlight used to apply light to a rear surface of the panel portion and which further comprises a backlight drive circuit that controls the brightness of the backlight according to a detection output of the thin-film photodiode.
